(19) United States
(12) Patent Application Publication
(10) Pub. No.: US 2026/0057164 A1
(43) Pub. Date: Feb. 26, 2026

(54) GENERATING INTEGRATED CIRCUIT PLACEMENTS USING NEURAL NETWORKS CONDITIONED ON TARGET REWARD VALUES

(71) Applicant: DeepMind Technologies Limited, London (GB)

(72) Inventors: Sergio Guadarrama Cotado, Berkeley, CA (US); Wenjie Jiang, Mountain View, CA (US); Vincent Zhuang, Menlo Park, CA (US); Ebrahim Songhori, San Jose, CA (US); Kuang-Huei Lee, San Francisco, CA (US)

(21) Appl. No.: 18/812,871

(22) Filed: Aug. 22, 2024

(51) Int. Cl. G06F 30/392; G06F 30/31; G06F 30/323; G06N 3/0464; G06N 3/09; G06N 3/092; G06N 3/096

(52) U.S. Cl. CPC G06F 30/392; G06F 30/31; G06F 30/323; G06N 3/0464; G06N 3/09; G06N 3/092; G06N 3/096

(57) ABSTRACT

Methods, systems, and apparatus, including computer programs encoded on computer storage media, for generating a computer chip placement.

### BACKGROUND

This specification relates to using neural networks for electronic design automation and, more specifically, for generating a computer chip placement.

Computer chip placements are schematic representations of the placement of some or all of the circuits of a computer chip on the surface, i.e., the chip area, of the computer chip.

Neural networks are machine learning models that employ one or more layers of nonlinear units to predict an output for a received input. Some neural networks include one or more hidden layers in addition to an output layer. The output of each hidden layer is used as input to the next layer in the network, i.e., the next hidden layer or the output layer. Each layer of the network generates an output from received inputs in accordance with current values of a respective set of parameters.

### SUMMARY

This specification describes a system implemented as computer programs on one or more computers in one or more locations that generates a chip placement for an integrated circuit. The integrated circuit for which the chip placement is being generated will be referred to in this specification as a “computer chip” but should generally be understood to mean any collection of electronic circuits that are fabricated on one piece of semiconductor material.

The chip placement places each node from a netlist of nodes at a respective location on the surface of the computer chip. In particular, the system uses a neural network (a “macro placement neural network”) to place the macro nodes in the netlist of nodes at respective locations on the surface of the computer chip.

Particular embodiments of the subject matter described in this specification can be implemented so as to realize one or more of the following advantages.

Floorplanning, which involves placing the components of a chip on the surface of the chip, is a crucial step in the chip design process. The placement of the components should optimize metrics such as area, total wire length and congestion. If a floorplan does not perform well on these metrics, the integrated circuit chip that is generated based on the floor plan will perform poorly. For example, the integrated circuit chip could fail to function, could consume an excessive amount of power, could have an unacceptable latency, or have any of a variety of other undesirable properties that are caused by sub-optimal placement of components on the chip.

The described techniques allow for a high-quality chip floorplan to be generated by making use of the described macro placement neural network and the described training techniques.

In particular, this specification describes how to, at inference, condition a macro placement neural network on a target reward function value to improve the quality of the final generated placement.

This specification also describes how the neural network can be trained on a large amount of varying quality placements through supervised learning in order to significantly improve the quality of the floorplans that are generated after training. That is, by making use of the described techniques, the neural network can be trained on a much larger range of available data because of the ability to incorporate placements of varying quality into the training. In particular, the availability of training data that reflects only high-quality placements may be limited due to the fact that generating high-quality placements for real-world netlists is a very challenging task. By making use of reward function value conditioning, the system can effectively incorporate sub-optimal or otherwise lower quality placements into the training, greatly increasing the amount of data available for use in training the macro placement neural network. Training on a larger range of available data then allows the neural network to be used to generate higher-quality placements after training.

This specification also describes techniques that allow users to “co-design” a placement with the macro placement neural network, effectively incorporating user domain expertise into the placement process in a flexible and adaptive manner. “Co-designing” a placement generally refers to generating a placement where some of the macro nodes are placed by a user while others are placed using the macro placement neural network.

The details of one or more embodiments of the subject matter described in this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1 shows an example placement generation system.

FIG. 2 illustrates the architecture of the macro placement neural network.

FIG. 3 is a flow diagram of an example process for training the macro placement neural network.

FIG. 4 is a flow diagram of an example process for placing a macro node at a given time step.

FIG. 5 shows an example co-design.

Like reference numbers and designations in the various drawings indicate like elements.

### DETAILED DESCRIPTION

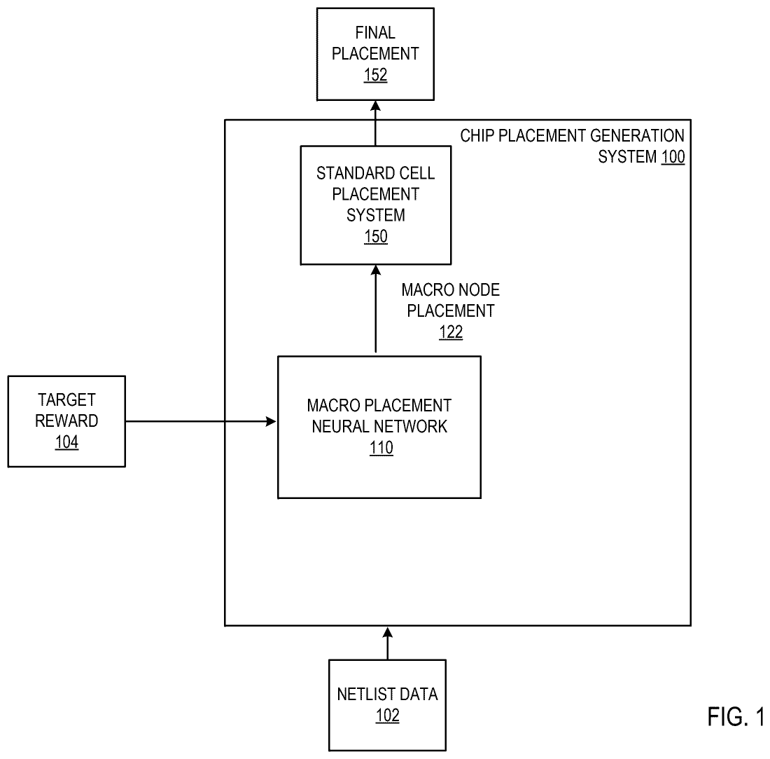

FIG. 1 shows an example placement generation system 100. The placement generation system 100 is an example of a system implemented as computer programs on one or more computers in one or more locations in which the systems, components, and techniques described below are implemented.

The system 100 receives netlist data 102 for a computer chip, i.e., a very large-scale integration (VLSI) chip, that is to be manufactured and that includes a plurality of integrated circuit components, e.g., memory components and components that implement logic functions. The plurality of integrated circuit components may be different depending on the desired function of the chip. For example, the chip can be a special-purpose chip, i.e., an application-specific integrated circuit (ASIC), for machine learning computations, video processing, cryptography, or another compute-intensive function.

The netlist data 102 is data describing the connectivity of the integrated circuit components of the computer chip. In particular, the netlist data 102 specifies a connectivity on the computer chip among a plurality of nodes that each correspond to one or more of a plurality of integrated circuit components of the computer chip. That is, each node corresponds to a respective proper subset of the integrated circuit components, and those subsets do not overlap. In other words, the netlist data 102 identifies, for each of the plurality of nodes, which other nodes (if any) the node needs to be connected to by one or more wires in the manufactured computer chip. In some cases, the integrated circuit components have already been clustered in clusters, e.g., by an external system or by using an existing clustering technique, and each node in the netlist data represents a different one of the clusters.

The system 100 generates, as output, a final computer chip placement 152 that places some or all of the nodes in the netlist data 102 at a respective position on the surface of the computer chip. That is, the final computer chip placement 152 identifies a respective position on the surface of the computer chip for some or all of the nodes in the netlist data 102 and, therefore, for the integrated circuit components that are represented by the node.

As one example, the netlist data 102 can identify two types of nodes: nodes that represent macro components and nodes that represent standard cell components.

Macro components are large blocks of IC components, e.g., static random-access memory (SRAM) or other memory blocks, that are represented as a single node in the netlist. For example, the nodes representing macro components can include nodes that each represent a corresponding instance of an SRAM. As another example, the nodes representing macro components can include hard macros that are made up of a fixed number of standard cells, e.g., a macro that is made up of a fixed number of instances of a register file. As another example, the nodes representing macro components can include one or more nodes that each represent a phase-locked loop (PLL) circuit to be placed on the chip. As yet another example, the nodes representing macro components can include one or more nodes that each represent a sensor to be placed on the chip.

Standard cell components are a group of transistor and interconnect structures, e.g., a group that provides a Boolean logic function (e.g., AND, OR, XOR, XNOR, inverters) or a group that provides a storage function (e.g., flip-flop or latch).

In some implementations, nodes in the netlist data represent a single standard cell component. In some other implementations, nodes in the netlist data represent already clustered standard cell components.

Generally, the placement 152 assigns each node to a grid square in an N×M grid overlaid over the surface of the chip, where N and M are integers.

In some implementations, the values of N and M are provided as inputs to the system 100.

In other implementations, the system 100 generates the values of N and M.

For example, the system 100 can treat choosing the optimal number of rows and columns as a bin-packing problem and rank different combinations of rows and columns by the amount of wasted space they incur on the surface of the chip. The system 100 can then select the combination that results in the least amount of wasted space as the values for N and M.

As another example, the system 100 can process an input derived from the netlist data, data characterizing the surface of the integrated circuit chip, or both using a grid generation machine learning model that is configured to process the input to generate an output that defines how to divide the surface of the integrated circuit chip into the N×M grid.

The system 100 includes a macro placement neural network 110 and a standard cell placement system 150.

The system 100 uses the macro placement neural network 110 to generate a macro node placement 122.

In particular, the macro node placement 122 places each macro node, i.e., each node representing a macro, in the netlist data 102 at a respective position on the surface of the computer chip.

The system 100 generates the macro node placement 122 by placing a respective macro node from the netlist data 102 at each time step in a sequence of a plurality of time steps.

That is, the system 100 generates the macro node placement auto-regressively, i.e., node-by-node over a number of time steps, with each macro node being placed at a location at a different one of the time steps, according to a macro node order. The macro node order orders the macro nodes, with each node that is before any given macro node in the macro node order being placed before the given macro node.

Prior to generating the macro node placement, the system 100 receives a target value 104 for a reward function that measures a quality of the placement of the respective netlist of nodes.

More specifically, the reward function measures certain characteristics of the generated placements that, when optimized, result in a chip that is manufactured using the generated placement exhibiting good performance, e.g., in terms of one or more of power consumption, heat generation, or timing performance.

Examples of reward functions are described in more detail below.

Generally, the target value 104 for the reward function specifies a value that should be achieved by a high-quality placement for the current netlist of nodes.

In some cases, the target value 104 is the same for all netlists that are placed by the system 100. As one example, the target value 104 can be received as input by the system. As another example, the target value 104 can be determined as a mean, median, or other aggregation measure of reward values for a subset of placements for netlists of nodes in training data used to train the neural network 110. As one example, the subset can include placements that have been determined to be high-quality placements, e.g., by a user of the system.

In some other cases, the target value 104 depends on certain criteria for the placement or for the fabricated chip, e.g., constraints on surface area, power consumption, heat generation and so on. For example, the target value 104 can be determined based on a respective baseline reward value for a baseline placement for the current netlist of nodes, e.g., one determined manually by a human user or by a different, default placer. As one example, the system can determine the target value 104 by selecting a value that is “better” by a threshold amount than the baseline reward value.

At each particular time step in the sequence, the system 100 generates an input representation for the particular time step and processes the input representation and the target value 104 using the macro placement neural network 110.

The input representation for a particular time step generally characterizes at least (i) respective positions on the surface of the chip of any macro nodes that are before a particular macro node to be placed at the particular time step in the macro node order and (ii) the particular macro node to be placed at the particular time step.

The input representation can also optionally include data that characterizes the connectivity between the nodes that is specified in the netlist data 102. For example, the input representation may characterize for, some or all of the nodes, one or more other of the nodes to which that node is connected according to the netlist. For example, the input representation can represent each connection between any two nodes as an edge connecting the two nodes.

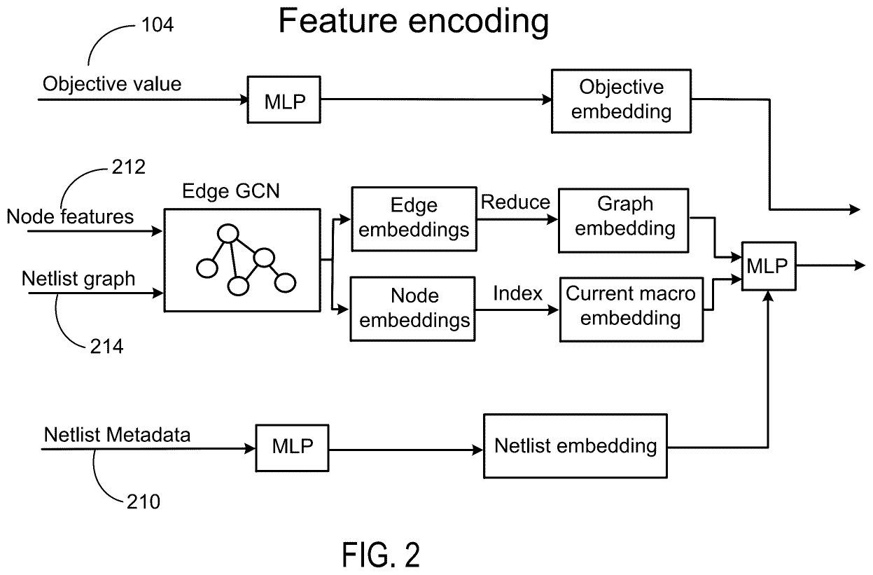

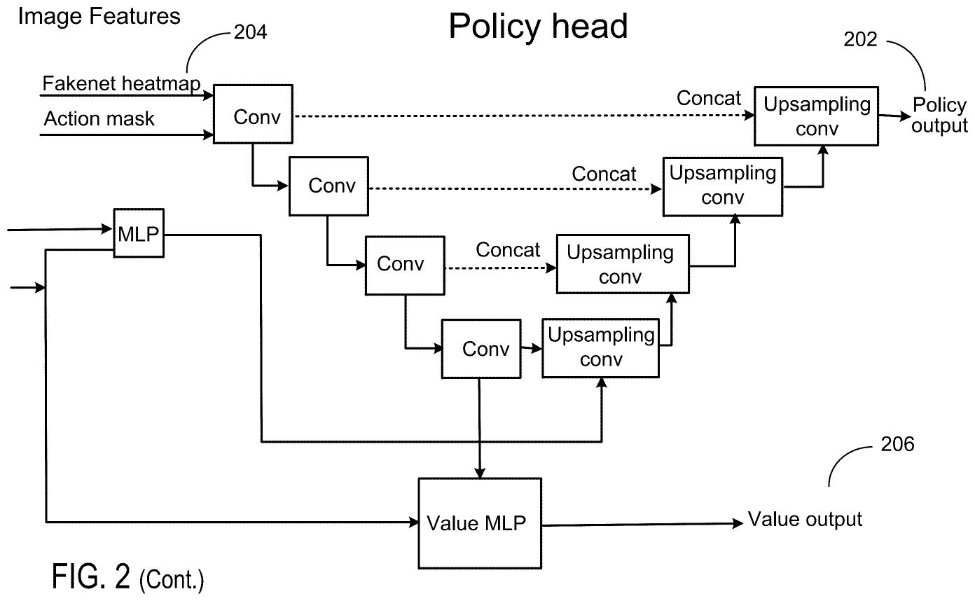

An example input representation is described in more detail below with reference to FIG. 2.

In the first time step of the sequence, the input representation indicates that no nodes have been placed and therefore indicates, for each node in the netlist, that the node does not yet have a position on the surface of the chip.

The macro placement neural network 110 is a neural network that has parameters (referred to in this specification as “network parameters”) and that is configured to process the input representation in accordance with current values of the network parameters to generate a score distribution, e.g., a probability distribution or a distribution of logits, over a plurality of positions on the surface of the computer chip. For example, the distribution can be over the grid squares in the N×M grid overlaid over the surface of the chip.

The system 100 then assigns the macro node to be placed at the particular time step to a position from the plurality of positions using the score distribution generated by the neural network.

The operations performed by the neural network 110 at a given time step and placing a node at the time step using the score distribution are described in more detail below with reference to FIGS. 2-4.

By adding macro nodes to the placement one by one, after the last time step in the sequence, the macro node placement will include a respective placement for all of the macro nodes in the netlist data 102.

Because the system 100 conditions the macro placement neural network 110 on the target value 104 of the reward function, the system 100 increases the likelihood that a final placement 152 generated by the system 100 will achieve the target value 104 when evaluated using the reward function.

Once the system 100 has generated the macro node placement 122, the standard cell placement system 150 generates the final computer chip placement 152 by placing each of the standard cells at a respective position on the surface of a partially placed integrated circuit chip that includes the macro components represented by the macro nodes placed according to the macro node placement, i.e., placed as in the macro node placement 122.

In some implementations, the system 150 clusters the standard cells into a set of standard cell clusters (or obtains data identifying already generated clusters) and then places each cluster of standard cells at a respective position on the surface of the partially placed integrated circuit chip using a graph placement technique. As a particular example, the engine 130 can cluster the standard cells using a partitioning technique that is based on the normalized minimum cut objective. An example of such a technique is hMETIS, which is described in Karypis, G. and Kumar, V. A hypergraph partitioning package. In HMETIS, 1998.

In some other implementations, the system 150 does not cluster the standard cells and directly places each standard cell at a respective position on the surface of the partially placed integrated circuit chip using the graph placement technique.

The graph placement technique can be any appropriate technique for placing nodes of a graph. For example, the engine 130 can use a force based technique, i.e., a force-directed technique. In particular, when using a force based technique, the system 150 represents the netlist as a system of springs that apply force to each node, according to the weight×distance formula, causing tightly connected nodes to be attracted to one another. Optionally, the engine 130 also introduces a repulsive force between overlapping nodes to reduce placement density. After applying all forces, the engine 130 moves nodes in the direction of the force vector. To reduce oscillations, the engine 130 can set a maximum distance for each move. Using force-directed techniques to place nodes is described in more detail in Shahookar, K. and Mazumder, P. Vlsi cell placement techniques. ACM Comput. Surv., 23(2):143220, June 1991. ISSN 0360-0300. doi: 10.1145/103724.103725.

In some implementations, the system 100 uses the initial placement as the final placement 152.

In some other implementations, the system 100 provides the initial placement as input to a legalization engine that adjusts the initial placement to generate the final placement 152.

In particular, the legalization engine 150 can generate a legalized integrated circuit chip placement by applying a greedy legalization algorithm to the initial integrated circuit chip placement. For example, the engine 150 can perform a greedy legalization step to snap macros onto the nearest legal position while honoring a set of minimum spacing constraints.

Optionally, the engine 150 can further refine the legalized placement or can refine the initial placement 132 directly without generating the legalized placement, e.g., by performing simulated annealing or by providing the legalized placement or the initial placement to an electronic design automation (EDA) software tool for evaluation and fine-tuning.

Optionally, the system 100 or an external system can then fabricate (produce) a chip (integrated circuit) according to the final placement 152. Such an integrated circuit may exhibit improved performance, e.g., have one or more of lower power consumption, lower latency, or smaller surface area, than one designed using a conventional design process, and/or be producible using fewer resources. The fabrication may use any known technique. In some cases, fabricating the chip according to the final placement can include presenting data identifying the placement to a user to allow the user to modify the final placement 152 before fabrication or providing the final placement 152 to an electronic design automation (EDA) for fine-tuning before fabrication.

The system 100 can receive the netlist data 102 in any of a variety of ways.

For example, the system 100 can receive the netlist data 102 as an upload from a remote user of the system over a data communication network, e.g., using an application programming interface (API) made available by the system 100. In some cases, the system 100 can then provide the final placement 152 to the remote user through the API provided by the system 100, e.g., for use in fabricating a chip according to the final placement 152.

As another example, the system 100 can be part of an electronic design automation (EDA) software tool and can receive the netlist data 102 from a user of the tool or from another component of the tool. In this example, the system 100 can provide the final placement 152 for evaluation by another component of the EDA software tool before the computer chip is fabricated.

FIG. 2 shows the architecture of the macro placement neural network 110 at a given time step.

As described above with reference to FIG. 1, at each time step during generation of a placement, the macro placement neural network 110 is configured to receive an input representation and a target reward function value 104 (objective value) and to process the input representation and the objective value to generate a policy output 202 that includes a score distribution, e.g., a probability distribution or a distribution of logits, over a plurality of locations on the surface of the computer chip.

Generally, the input representation includes least (i) data characterizing respective positions on the surface of the chip of any macro nodes that are before a particular macro node to be placed at the particular time step in the macro node order and (ii) data characterizing the particular macro node to be placed at the particular time step.

As shown in FIG. 2, the macro placement neural network 110 includes a feature encoding neural network, a policy neural network, and, optionally, a value neural network.

The feature encoding neural network is configured to, at each particular time step, process the input representation to generate an encoded representation 212 of the input representation. An encoded representation is a numeric representation in a fixed dimensional space, i.e., an ordered collection of a fixed number of numeric values. For example, the encoded representation can be a vector or a matrix of floating point values or other types of numeric values.

The feature encoding neural network is also configured to process the target value 104 to generate an encoded representation of the target value 104. For example, the feature encoding neural network can process the target value 104 using a target value encoder, e.g., a multi-layer perceptron (MLP) or other appropriate neural network, a single time prior to beginning to generate the placement to generate the encoded representation of the target value 104 and then re-use the encoded representation of the target value 104 at each time step.

The policy neural network is configured to, at each particular time step, process the encoded representation of the input representation and the encoded representation of the target value 104 to generate the policy output 202.

Generally, the policy neural network 220 can have any appropriate architecture that allows the policy neural network 220 to map the encoded representations to a score distribution.

For example, the policy neural network can be a deconvolutional neural network that includes a fully-connected neural network followed by a set of de-convolutional layers. The policy neural network can optionally include other types of neural network layers, e.g., batch normalization layers or other kinds of normalization layers.

In other examples, the policy neural network can include one or more recurrent neural network layers, e.g., long short-term memory (LSTM) layers, gated recurrent unit (GRU) layers, or other types of recurrent layers, one or more self-attention layers, or both, along with an output layer that generates the scores for the positions. For example, when the scores are probabilities, the output layer can be a softmax layer.

In the example of FIG. 2, the policy neural network also receives, as input, image features 204 of the partial placement as of the time step. In particular, in the example of FIG. 2, the input image features 204 include a heatmap and an action mask.

More generally, the input image features 204 can include a heatmap, an action mask, or both.

When included, the heatmap can represent a graph of macros, i.e., of the current macro for the time step and already placed macros, where the connections between macros are determined by the connectivity strength of the timing paths between the macros in the netlist. That is, the graph can include nodes that represent the already placed macros and edges that connect the nodes representing the macros.

As a particular example, each edge in the graph can have a connection weight, with the connection weight being a weighted sum of the number of connections with N-hop flip-flops between the macros represented by the nodes connected by the edge. Generally, the weights are decreasing, so that the weight for a smaller number of hops is not smaller than the weight for any larger number of hops. Optionally, the weight can become zero after the number of hops are greater than a specific number, i.e., which implies that long hop connections are ignored. As a particular example, for N=[0, 1, 2, 3, 4, . . . ] the corresponding weight can be: [16, 8, 4, 2, 0, . . . ], indicating that the weight becomes zero for N>=4.

A cost can be calculated for a macro placement based on the weighted sum of the Euclidean distance between macros using the weights between them in the graph. That is, the cost for a given placement can be equal to the sum of, for each pair of macros in the graph, the product between the Euclidean distance between the macros in the placement and the weight for the edge corresponding to the pair of macros.

The heatmap for a given macro and a partial macro placement can be based on, for each grid location, the additional cost for placing the macro at the grid location given the location of the already placed macros. That is, for each grid location, the value for the grid location in the heatmap can be based on the difference between (i) the cost of a placement that places the given macro at the grid location and (ii) the cost of the placement that includes only the already placed macros. For example, the value can be equal to the negative of the difference, equal to one divided by the difference, a normalized version of one of the negative of the difference or one divided by the difference, or a different value that is computed from the difference that results in the heatmap having the largest value where the additional cost is minimized and vice versa.

The system also tracks the density of the positions on the chip, i.e., of the squares in the grid. In particular, the system maintains a density value for each position that indicates the degree to which that position is occupied. When a node has been placed at a given position, the density value for that position is set equal to one (or to a different maximum value that indicates that the position is fully occupied). When no node has been placed at the given position, the density value for that position indicates the number of edges that pass through the position. The density value for a given position can also reflect blockages, e.g., clock straps or other structures that block certain parts of the chip surface, by setting the values for those positions to one.

In the example of FIG. 2, the system uses these densities to generate an action mask which can used as part of the image features 204, i.e., as a mask in which the value for any position that has a density that is above a threshold value is zero and the value for any position that has a density that is not above the threshold value is one, to generate the modified score distribution.

As a particular example, the threshold can be equal to one and the system can set the score for any position at which a node has already been placed, i.e., that has a density value of one, to zero. As another example, the threshold can be less than one, indicating that the system also sets the score to zero for any position that does not have a node but that has too many wires running through it (i.e., the number of wires associated with a position is above a threshold).

The policy neural network processes the image features 204 through a convolutional neural network, e.g., one having a U-Net architecture as shown in FIG. 2, to generate the policy output 202.

In order to condition on the encoded representations of the input representation and the target reward value 104, one or more intermediate layers of the convolutional neural network can be conditioned on the encoded representations. For example, in the example of FIG. 2, an upsampling convolutional layer is conditioned on the encoded representations. A given layer can be conditioned on the encoded representations in any appropriate way. For example, a cross-attention layer can be inserted before or after the given layer that cross-attends into the encoded representations. As another example, the layer can be conditioned on the encoded representation through a Feature-wise Linear Modulation (FILM) layer before or after the given layer that modulates the input or output of the layer using the encoded representations. As yet another example, the given layer can have a gated activation function that is conditioned on the encoded representations.

The value neural network, when used, is configured to, at each particular time step, process the encoded representation of the input representation to generate a value estimate 206 that estimates a value of a current state of the placement as of the particular time step. The value of the current state is an estimate of the output of a reward function for a placement that is generated starting from the current state, i.e., starting from the current, partial placement. For example, the value neural network can be a recurrent neural network or can be a feedforward neural network, e.g., one that includes one or more fully-connected layers, e.g., an MLP.

Optionally, as shown in the example 200, the value neural network can also process, in addition to the encoded representation of the input representation, an intermediate output of the policy neural network, e.g., the output of an intermediate convolutional layer of the policy neural network as shown in FIG. 2.

However, as shown in FIG. 2, the value neural network is generally not conditioned on the encoded representation of the target reward value 104. Thus, the value prediction 204 is an independent prediction of the final reward value, i.e., independent of the target reward value 104 that is provided as input to the neural network 110.

This value estimate can be used during the fine-tuning of the neural network 110, i.e., when using a reinforcement learning technique that relies on value estimates being available. In other words, when the reinforcement learning technique used to fine-tune the macro placement neural network requires a value estimate, the macro placement neural network 110 also includes the value neural network 230 that generates the value estimates that are required by the reinforcement learning technique.

Training the macro placement neural network 110 will be described in more detail below.

As shown in the example of FIG. 2, the input feature representation includes a respective vectorized representation of some or all of the nodes in the netlist (“node features” 212) and “netlist graph” data 214 that represents the connectivity between nodes in the netlist as edges that each connect two respective nodes in the netlist data. As a particular example, the input feature representation can include a respective vectorized representation of only the macro nodes, of the macro nodes and the clusters of standard cells, or of the macro nodes and the standard cell nodes.

Each vectorized representation characterizes the corresponding node. In particular, for each node that has already been placed, the vectorized representation includes data identifying the position of the node on the surface of the chip, e.g., the coordinates of the center of the node or of some other designated part of the node, and for each node that has not already been placed, the vectorized representation includes data indicating that the node has not yet been placed, e.g., includes default coordinates that indicate that the node has yet to be placed on the surface of the chip. The vectorized representation can also include other information that characterizes the node, e.g., the type of the node, the dimensions of the node, e.g., the height and width of the node, and so on.

In the example of FIG. 2, the feature encoding neural network includes a graph encoder neural network that processes the vectorized representations of the nodes in the netlist to generate (i) a graph embedding of the vectorized representations of the nodes in the netlist and (ii) a current macro embedding that represents the macro node to be placed at the particular time step. For example, the graph encoder neural network can generate a respective node embedding for each node in the graph and then select the node embedding of the macro node to be placed at the particular time step as the current macro embedding.

An embedding is a numeric representation in a fixed dimensional space, i.e., an ordered collection of a fixed number of numeric values. For example, the embedding can be a vector or a matrix of floating point values or other type of numeric values.

For example, the graph encoder neural network can initialize a respective edge embedding for each edge in the netlist data, e.g., randomly, and initialize a respective node embedding for each node in the netlist data, i.e., so that the node embedding is equal to the respective vectorized representation for the node.

The graph encoder neural network can then repeatedly update the node and edge embeddings by updating the embeddings at each of a plurality of message passing iterations.

After the last message passing iteration, the graph encoder neural network generates the netlist embedding and the current node embedding from the node and edge embeddings.

As a particular example, the graph encoder neural network can generate the netlist embedding by combining the edge embeddings after the last message passing iteration. For example, the system can compute the netlist embedding by applying a reduce mean function on the edge embeddings after the last message passing iteration.

As another particular example, the graph encoder neural network can set the current macro embedding for the current node to be equal to the embedding for the current macro after the last message passing iteration.

The graph encoder neural network can use any of a variety of message passing techniques to update the node and edge embeddings at each message passing iteration.

As a particular example, at each message passing iteration, the graph encoder neural network updates the edge embedding for each edge using the respective node embeddings for the two nodes connected by the edge.

At each iteration, to update the embedding for a given edge, the graph encoder network generates an aggregated representation from at least the node embeddings for the two nodes connected by the edge and processes the aggregated representation using a first fully-connected neural network to generate the updated edge embedding for the given edge. In some implementations, each edge has the same weight, i.e., one, in the netlist data. In some other implementations, each edge is associated with a respective weight in the netlist data, and the system generates the aggregated representation from the node embeddings for the two nodes connected by the edge and the weight associated with the edge in the netlist data. The weights for each edge can be, e.g., learned jointly with the training of the neural network.

To update the embedding for a given node at a given message passing iteration, the graph encoder updates the node embedding for the node using the respective edge embeddings for the edges that are connected to the node. For example, the graph encoder can average the respective edge embeddings for the edges that are connected to the node.

The input feature representation can also optionally include “netlist metadata” 210 that characterizes the netlist of nodes. The netlist metadata can include any appropriate information that characterizes the netlist. For example, the information could include any of information about the underlying semiconductor technology (horizontal and vertical routing capacity), the total number of nets (edges), macros, and standard cell clusters in the netlist, canvas size, i.e., size of the surface of the chip, or the number of rows and columns in the grid.

When the input feature representation includes netlist metadata, the feature encoding neural network can include a fully-connected neural network, e.g., an MLP, that processes the metadata to generate a netlist metadata embedding.

The feature encoding neural network generates the encoded representation of the input representation from at least the netlist embedding of the vectorized representations of the nodes in the netlist and the current node embedding that represents the macro node to be placed at the particular time step. When the feature encoding neural network also generates a netlist metadata embedding, the system also uses the netlist metadata embedding to generate the encoded representation.

As a particular example, the neural network can concatenate the netlist embedding, the current node embedding, and the netlist metadata embedding and then process the concatenation using a fully-connected neural network, e.g., an MLP, to generate the encoded representation.

As described above, the system tracks the density of the positions on the chip, i.e., of the squares in the grid.

Once the policy neural network 220 has generated the score distribution at the time step, the system uses the density to generate a modified score distribution and then assigns the node corresponding to the time step using the modified score distribution. In particular, the system modifies the score distribution by setting the score for any position that has a density value that satisfies, e.g., exceeds, a threshold to zero.

For example, the system can assign the node to the position having the highest score in the modified score distribution or sample a position from the modified score distribution, i.e., so that each position has a likelihood of being selected that is equal to the likelihood, and then assign the node to the sampled position.

In order for the neural network 110 to be used to generate high quality placements, the system (or another system) trains the neural network on training data.

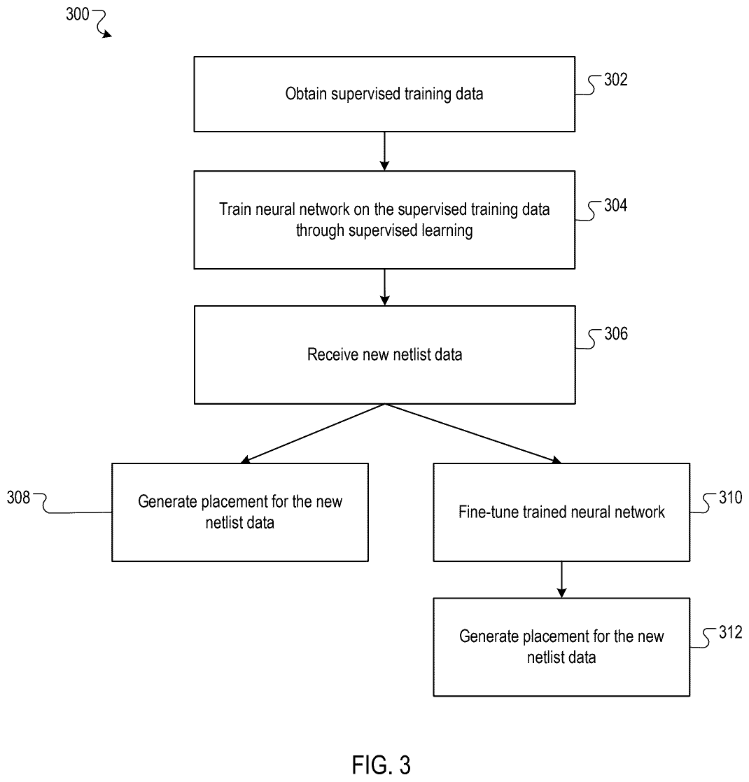

FIG. 3 is a flow diagram of an example process 300 for training a macro placement neural network. For convenience, the process 300 will be described as being performed by a system of one or more computers located in one or more locations. For example, a placement generation system, e.g., the placement generation system 100 of FIG. 1, appropriately programmed, can perform the process 300.

The system can perform the process 300 to train the macro placement neural network, i.e., to determine trained values of the network parameters.

In some implementations, the system distributes the training of the macro placement neural network across many different workers, i.e., across many different homogenous or heterogeneous computing devices, i.e., devices that perform training computations using CPUs, GPUs, or ASICs. In some of these implementations, some or all of the steps 300 can be performed in parallel by many different workers operating asynchronously from one another in order to speed up the training of the macro placement neural network. In other implementations, the different workers operate synchronously to perform some or all of the steps of the process 300 in parallel in order to speed up the training of the neural network.

The system obtains supervised training data (step 302).

The supervised training data includes multiple different training examples that each correspond to a particular macro node from a particular netlist of nodes. The training example includes (i) an input representation that specifies the state of the placement of the particular netlist of nodes as of the particular macro node, (ii) a respective actual value of a reward function that measures a quality of the final placement of the respective netlist of nodes that resulted from the entire particular netlist being placed, (iii) a placement location for the particular macro node in the final placement.

More specifically, the reward function measures certain characteristics of the generated placements that, when optimized, result in a chip that is manufactured using the generated placement exhibiting good performance, e.g., in terms of one or more of power consumption, heat generation, or timing performance.

In particular, the reward function includes a respective term for one or more characteristics. For example, when there are multiple terms, the reward function can be a sum or a weighted sum of the multiple terms.

As one example, the reward function can include a wire length measure, i.e., a term that measures wire length of the wires on the surface of the chip, that is higher when the wire length between nodes on the surface of the chip is shorter.

For example, the wire length can be the negative of the Manhattan distance or other distance measure between all of the adjacent nodes on the surface of the chip.

As another example, the wire length measure can be based on half-perimeter wirelength (HPWL), which approximates the wire length using the half-perimeter of the bounding boxes for all nodes in the netlist. When computing the HPWL, the system can assume that all wires leaving a standard cell cluster originate at the center of the cluster. In particular, the system can compute the HPWL for each edge in the netlist and then compute the wire length measure as equal to the negative of a normalized sum of the HPWLs for all of the edges in the netlist.

Including a term that measures the wire length in the reward function has the advantage that write length roughly measures wiring cost and also correlates with other important metrics, such as power and timing.

As another example, the reward function can include a congestion measure, i.e., a term that measures congestion, that is higher when congestion on the surface of the computer chip is lower. Congestion is a measure of the difference between available wiring resources in a given region (not necessarily a contiguous region) on the chip versus the actual wires that run through the region. For example, the congestion may be defined as the ratio of the wires that run through the region in the generated placement to the available wiring resources (e.g., a maximum number of wires which can run though that region). As a particular example, the congestion measure can track the density of wires across the horizontal and vertical edges of the surface.

In particular, the system can make use of a routing model for the netlist (e.g., net bounding box, upper L, lower L, A*, minimum spanning tree, or actual routed net, and so on). Based on this routing model, the congestion measure can be calculated by determining the ratio of, for each position on the surface, the available wiring resources in the placement versus wiring estimates from the routing model for the position.

As another example, the system can compute the congestion measure by keeping track of vertical and horizontal allocations at each position separately, e.g., computed as described above. The system can then smooth the congestion estimate by running convolutional filters, e.g., 5×1 convolutional filters or differently sized filters depending on the number of positions in each direction, in both the vertical and horizontal direction. The system can then compute the congestion measure as the negative of the average of the top 10%, 15%, or 20% of the congestion estimates.

As another example, the reward function can include a timing term, i.e., a term that measures timing of the digital logic, that is higher when the performance of the chip is better (e.g., the reward function takes a correspondingly a higher value for placements of respective chips which take less time to perform a certain computational task). Timing or performance of a placement can be measured using static timing analysis (STA). This measurement can include calculating stage delays over logic paths (including internal cell delays and wire delays) and finding critical paths that would determine the maximum speed the clock can run for safe operation. For a realistic view of timing, logic optimization may be necessary to accommodate paths getting longer or shorter as node placements are in progress.

As another example, the reward function can include one or more terms that measure the power or energy that would be consumed by the chip, i.e., one or more terms that are higher when the power that would be consumed by the chip is lower.

As another example, the reward function can include one or more terms that measure the area of the placement, i.e., that are higher when the area taken up by the placement is lower.

The system can generate the training examples using any of a variety of data sources. In particular, during training on a given training example, the system conditions the macro placement neural network on the actual reward value in the training example (rather than a target reward value as described above). This allows the system to incorporate both high performing placements and poorly performing placements into the training data.

As a particular example, the system can generate the supervised labeled dataset by sampling placements from reinforcement learning (RL) training trajectories of other macro placement neural networks on existing netlists. To increase sample diversity in the dataset, the system can include in the dataset both good (placements with high reward values) and bad (placements with low reward values) placement samples from the RL trajectory during training.

In some cases, the system also includes placements generated by human design experts in the dataset. These placements can be created manually by users, or by allowing users to modify placements generated by other neural networks.

As another example, the system can generate an initial dataset as described above, and then modify the initial dataset by performing one or more iterations of self-improvement on the initial training dataset. At each self-improvement iteration, the system can train a base model and then perform single-task reinforcement learning fine-tuning (as described below) on each netlist in the initial data set, producing additional placements that the system then adds to the data set.

As another example, the system can also use data augmentation to increase the size and diversity of the training data set. For example, for each placement, the system can generate additional training data by varying the size of the placement grid, e.g., over the top-k plausible resolutions of the placement grid.

In some cases, rather than generate the training data as described above, the system receives the supervised training data from another system.

The system trains the macro placement neural network on the supervised training data through supervised learning (step 304).

For example, the system can train the macro placement neural network to optimize an objective function, e.g., a cross entropy loss, that measures, for a given training example, an error between the policy output generated by the macro placement neural network and the actual placement in the training example.

When the macro placement neural network also includes the value neural network, the objective can also include a loss, e.g., an L2 loss, between the value prediction generated by the value neural network and the actual reward value.

For example, the overall loss can be a weighted combination of the cross-entropy loss and the value loss.

Generally, the system can perform the supervised training iteratively. At each iteration, the system can sample a batch of training examples from the supervised training data and train the macro placement neural network on the sampled batch of training data, e.g., by computing gradients of the objective function described above. The system can then apply an optimizer to the gradients to update the parameters of the macro placement neural network. A given batch of training examples can include multiple different training examples that correspond to multiple different netlists of nodes.

The system receives new netlist data and a target value of the reward function (step 306). The target value of the reward function reflects a desired combination of the one or more terms above for the integrated circuit that will be generated from a placement generated for the new netlist data by the system.

In some implementations, the system generates an integrated circuit placement for the new netlist data using the trained macro placement neural network, i.e., by placing a respective node from the new netlist data at each of a plurality of time steps using score distributions generated by the trained macro placement neural network while the macro placement neural network is conditioned on the target value of the reward function (step 308). That is, the system generates the placement for the new netlist data without training the macro placement neural network any further.

That is, by training the neural network through supervised learning, the system trains the macro placement neural network to generalize to new netlists without any additional training.

In some other implementations, to further improve the quality of the placement that is generated for the new netlist, the system first fine-tunes the trained macro placement neural network on the new netlist data through reinforcement learning (step 310) and then generates an integrated circuit placement for the new netlist data using the fine-tuned macro placement neural network (step 312) as described above.

In particular, while training the policy neural network through reinforcement learning on a given netlist for a given chip, the system can use the placement neural network to place the macro nodes in the given netlist one-by-one as described above. After the macro nodes have been placed, the system can place the standard cell nodes as described above to determine a final placement.

When performing the fine-tuning, the system can select the target reward value to be included as part of the input to the neural network as described above, e.g., either as a fixed value that is the same for different placements or a placement-specific value determined based on the placement.

The system can then evaluate the reward function to compute a reward value for the final placement, e.g., by computing the required quantities described above. After computing the reward value, the system can use the reward value, the macro node placements, and the score distributions generated by the placement neural network to train the placement neural network through reinforcement learning. Thus, while the placement neural network is only used to place the macro nodes, the reward values are computed only after the standard cell nodes have also been placed, ensuring that the placement neural network generates macro node placements that still allow for high quality placements of standard cell nodes.

The system can use any of a variety of reinforcement learning techniques to train the macro placement neural network.

For example, the system can use a policy gradient technique, e.g., REINFORCE or Proximal Policy Optimization (PPO), for the training. In these cases, when the neural network includes the value prediction neural network, the value prediction generated by the value neural network can be used to compute the baseline value that modifies the reward function value when computing the gradient of the reinforcement learning loss function.

The system can repeatedly perform the fine-tuning for different generated placements, e.g., until a threshold amount of time has elapsed, the neural network has been trained on a threshold number of placements, or the performance of the neural network has converged.

In some cases, the system can select different target reward values for different placements, e.g., by generating a range of candidate target reward values and selecting the target reward value for any given value from the given range. For example, the system can select a range of values that is centered at or otherwise includes the aggregation measure of reward values described above. As another example, the system can select a range of values based on the reward value for the baseline placement for the netlist.

In some of these examples, to account for the fact that the value network is trained purely on offline data, the system can “warm up” the value network at the beginning of RL finetuning by freezing the macro placement neural network for some number of initial iterations and only updating the value network. This can ensure that the policy defined by the macro placement neural network the value predictions generated by the value network are reasonably close before the value predictions are used to update the macro placement neural network.

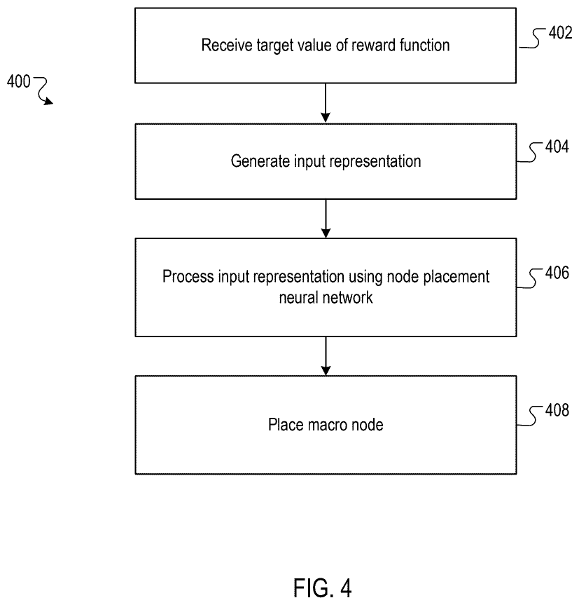

FIG. 4 is a flow diagram of an example process 400 for placing a macro node at a given time step. For convenience, the process 400 will be described as being performed by a system of one or more computers located in one or more locations. For example, a placement generation system, e.g., the placement generation system 100 of FIG. 1, appropriately programmed, can perform the process 400.

The system can perform the process 400 for each time step in the sequence of time steps to place each macro node according to the macro node order.

In some implementations, the system receives the macro node order as an input along with the netlist data.

In some other implementations, the system can generate the macro node order from the netlist data.

As one example, the system can order the macro nodes according to size, e.g., by descending size, and break ties using a topological sort. By placing larger macros first, the system reduces the chance of there being no feasible placement for a later macro. The topological sort can help the policy network learn to place connected nodes close to one another.

As another example, the system can process an input derived from the netlist data through a macro node order prediction machine learning model that is configured to process the input derived from the netlist data to generate an output that defines the macro node order.

As yet another example, the macro placement neural network can be further configured to generate a probability distribution over the macro nodes. Then, the system can generate the macro node order dynamically by, for each particular time step in the plurality of time steps, selecting the macro node to be placed at the next time step after the particular time step based on the probability distribution over the macro nodes. For example, the system can select the macro node that has yet to be placed that has the highest probability.

Prior to performing the placement at the first time step, the system receives data specifying a target value for the reward function (step 402).

The system generates, from the netlist data, an input representation that characterizes at least (i) respective positions on the surface of the chip of any macro nodes that are before a particular macro node to be placed at the given time step in the macro node order and (ii) the particular macro node to be placed at the given time step (step 404). Optionally, the input representation can also include other information about the nodes in the netlist, netlist metadata, or both. An example of the input representation is described above with reference to FIG. 2.

The system processes the input representation using a macro placement neural network having a plurality of parameters (“network parameters”) (step 404). The macro placement neural network is configured to process the input representation in accordance with current values of the network parameters to generate a score distribution over a plurality of positions on the surface of the integrated circuit chip.

The system assigns the macro node to be placed at the particular time step to a position from the plurality of positions using the score distribution (step 406). As described above, the system can modify the score distribution based on the tracked density of the current placement, i.e., by setting the scores for any positions that have a density value that satisfies a threshold value to zero, and then select a position from the modified score distribution.

In some implementations, the system can further modify the score distribution using additional information.

In particular, as described above, in some implementations the neural network is trained on multiple different placements for multiple different netlists for multiple different chips. This can require the neural network to generate score distributions over differently sized chip surfaces. That is, when the plurality of positions are grid squares from an N×M grid overlaid over the surface of the integrated circuit chip, different chips can have different values for N and M. To account for this, the system can configure the neural network to generate scores over a fixed size maxN×maxM grid. When the value of N for the current chip is less than maxN, the system can set to zero the scores for the extra rows. Similarly, when the value of M for the current chip is less than maxM, the system can set to zero the scores for the extra columns.

Thus by repeatedly performing the process 400 the system can generate a placement for the macros in the netlist and then, as described above, generate a final placement after the macros have been placed.

In some implementations, the system can generate multiple different candidate placements, where some or all of the candidates are generated by conditioning the macro placement neural network on different target reward values, e.g., that are each selected from a range of candidate target reward values as described above. In these implementations, the system can determine a respective reward value for each candidate placement and then select, as the final placement, the candidate placement that has the highest reward value.

The above description generally describes that the macro placement neural network is conditioned on a value, e.g., a target value at inference and an actual value during supervised training, of the reward function. In some implementations where the reward function is a combination of multiple terms, in addition to the conditioning on the reward function value or instead of conditioning on the reward function value, the macro placement neural network can be conditioned on respective values for each of one or more terms of the reward function. This conditioning can be performed in the same manner as described above for the reward function value. Conditioning on reward function terms can allow the system to generate floorplans that satisfy respective criteria for each of one or more specific characteristics instead of or in addition to floorplans that satisfy criteria for overall reward values which may depend on multiple different characteristics.

The above description generally describes that the system uses the macro placement neural network to place each of the macro nodes at the netlist. In some cases, however, the system can allow a user to submit inputs specifying the placements of some of the macro nodes in the netlist.

For example, the system can, after placing a given macro node, provide an output for presentation to the user that shows the position of the given macro node and the other already placed macro nodes. The system can then allow the user to modify the position of the given macro node, e.g., by submitting an input through a user interface.

As another example, the system can, prior to placing a given macro node, provide an output for presentation to the user that identifies the given macro node and shows the positions of the other already placed macro nodes. The system can then allow the user to specify the placement of the given macro node, e.g., by submitting an input through a user interface.

Thus, the system can perform a “co-design” with a user, with some of the node placements in the final placement being generated by the macro placement neural network and others of the placements being generated by a user.

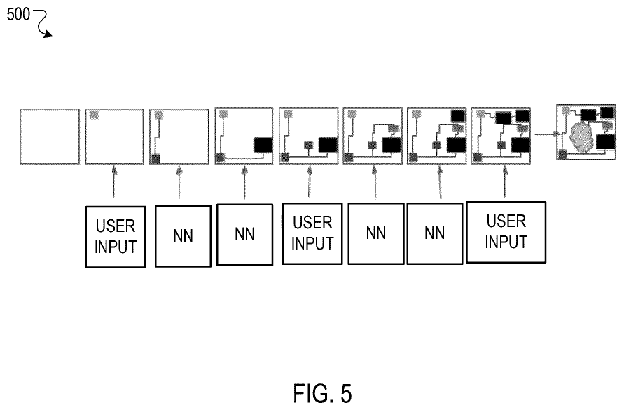

FIG. 5 shows an example 500 of a co-design.

As shown in the example 500, the netlist includes seven macro nodes. The system receives a user input specifying the placement of the first macro node in the order and then uses the macro placement neural network (“NN”) to place the next two nodes in the order. The system then receives a user input specifying the placement of the fourth macro node in the order and then uses the macro placement neural network to place the next two nodes in the order. Finally, the system receives a user input specifying the placement of the seventh and last macro node in the order, yielding a final placement that includes some nodes placed by the user and some nodes placed using the macro placement neural network.

Many existing placement algorithms have been designed to automatically generate macro placements at production quality. However, human placement is still very competitive with these approaches, and it is often difficult to capture and include human design knowledge in hand-crafted algorithms. The described system, on the other hand, allows for generating a co-design like the one shown in the example 500 that is able to leverage human design knowledge.

First, due to the auto-regressive nature of the system, users can recommend placement locations for some macros that they are confident with based on their domain knowledge, and let the neural network generate the placement for other macros. Macros that are placed by the neural network or by users can be interleaved in the sequence of node placement decisions, thereby allowing user placements to influence future placements by the neural network and vice versa.

This specification uses the term “configured” in connection with systems and computer program components. For a system of one or more computers to be configured to perform particular operations or actions means that the system has installed on it software, firmware, hardware, or a combination of them that in operation cause the system to perform the operations or actions. For one or more computer programs to be configured to perform particular operations or actions means that the one or more programs include instructions that, when executed by data processing apparatus, cause the apparatus to perform the operations or actions.

Embodiments of the subject matter and the functional operations described in this specification can be implemented in digital electronic circuitry, in tangibly-embodied computer software or firmware, in computer hardware, including the structures disclosed in this specification and their structural equivalents, or in combinations of one or more of them. Embodiments of the subject matter described in this specification can be implemented as one or more computer programs, i.e., one or more modules of computer program instructions encoded on a tangible non transitory storage medium for execution by, or to control the operation of, data processing apparatus. The computer storage medium can be a machine-readable storage device, a machine-readable storage substrate, a random or serial access memory device, or a combination of one or more of them. Alternatively or in addition, the program instructions can be encoded on an artificially generated propagated signal, e.g., a machine-generated electrical, optical, or electromagnetic signal, that is generated to encode information for transmission to suitable receiver apparatus for execution by a data processing apparatus.

The term “data processing apparatus” refers to data processing hardware and encompasses all kinds of apparatus, devices, and machines for processing data, including by way of example a programmable processor, a computer, or multiple processors or computers. The apparatus can also be, or further include, special purpose logic circuitry, e.g., an FPGA (field programmable gate array) or an ASIC (application specific integrated circuit). The apparatus can optionally include, in addition to hardware, code that creates an execution environment for computer programs, e.g., code that constitutes processor firmware, a protocol stack, a database management system, an operating system, or a combination of one or more of them.

A computer program, which may also be referred to or described as a program, software, a software application, an app, a module, a software module, a script, or code, can be written in any form of programming language, including compiled or interpreted languages, or declarative or procedural languages; and it can be deployed in any form, including as a stand alone program or as a module, component, subroutine, or other unit suitable for use in a computing environment. A program may, but need not, correspond to a file in a file system. A program can be stored in a portion of a file that holds other programs or data, e.g., one or more scripts stored in a markup language document, in a single file dedicated to the program in question, or in multiple coordinated files, e.g., files that store one or more modules, sub programs, or portions of code. A computer program can be deployed to be executed on one computer or on multiple computers that are located at one site or distributed across multiple sites and interconnected by a data communication network.

In this specification, the term “database” is used broadly to refer to any collection of data: the data does not need to be structured in any particular way, or structured at all, and it can be stored on storage devices in one or more locations. Thus, for example, the index database can include multiple collections of data, each of which may be organized and accessed differently.

Similarly, in this specification the term “engine” is used broadly to refer to a software-based system, subsystem, or process that is programmed to perform one or more specific functions. Generally, an engine will be implemented as one or more software modules or components, installed on one or more computers in one or more locations. In some cases, one or more computers will be dedicated to a particular engine; in other cases, multiple engines can be installed and running on the same computer or computers.

The processes and logic flows described in this specification can be performed by one or more programmable computers executing one or more computer programs to perform functions by operating on input data and generating output. The processes and logic flows can also be performed by special purpose logic circuitry, e.g., an FPGA or an ASIC, or by a combination of special purpose logic circuitry and one or more programmed computers.

Computers suitable for the execution of a computer program can be based on general or special purpose microprocessors or both, or any other kind of central processing unit. Generally, a central processing unit will receive instructions and data from a read only memory or a random access memory or both. The elements of a computer are a central processing unit for performing or executing instructions and one or more memory devices for storing instructions and data. The central processing unit and the memory can be supplemented by, or incorporated in, special purpose logic circuitry. Generally, a computer will also include, or be operatively coupled to receive data from or transfer data to, or both, one or more mass storage devices for storing data, e.g., magnetic, magneto optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device, e.g., a universal serial bus (USB) flash drive, to name just a few.

Computer readable media suitable for storing computer program instructions and data include all forms of non volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks.

To provide for interaction with a user, embodiments of the subject matter described in this specification can be implemented on a computer having a display device, e.g., a CRT (cathode ray tube) or LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's device in response to requests received from the web browser. Also, a computer can interact with a user by sending text messages or other forms of message to a personal device, e.g., a smartphone that is running a messaging application, and receiving responsive messages from the user in return.

Data processing apparatus for implementing machine learning models can also include, for example, special-purpose hardware accelerator units for processing common and compute-intensive parts of machine learning training or production, i.e., inference, workloads.

Machine learning models can be implemented and deployed using a machine learning framework, e.g., a TensorFlow framework or a Jax framework.

Embodiments of the subject matter described in this specification can be implemented in a computing system that includes a back end component, e.g., as a data server, or that includes a middleware component, e.g., an application server, or that includes a front end component, e.g., a client computer having a graphical user interface, a web browser, or an app through which a user can interact with an implementation of the subject matter described in this specification, or any combination of one or more such back end, middleware, or front end components. The components of the system can be interconnected by any form or medium of digital data communication, e.g., a communication network. Examples of communication networks include a local area network (LAN) and a wide area network (WAN), e.g., the Internet.

The computing system can include clients and servers. A client and server are generally remote from each other and typically interact through a communication network. The relationship of client and server arises by virtue of computer programs running on the respective computers and having a client-server relationship to each other. In some embodiments, a server transmits data, e.g., an HTML page, to a user device, e.g., for purposes of displaying data to and receiving user input from a user interacting with the device, which acts as a client. Data generated at the user device, e.g., a result of the user interaction, can be received at the server from the device.

While this specification contains many specific implementation details, these should not be construed as limitations on the scope of any invention or on the scope of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

Aspects of the present disclosure may be as set out in the following clauses:

Clause 1. A method performed by one or more computers, the method comprising:
obtaining netlist data for an integrated circuit chip, wherein the netlist data specifies a connectivity on the integrated circuit chip between a plurality of nodes that each correspond to one or more of a plurality of integrated circuit components of the integrated circuit chip, and wherein the plurality of nodes comprise macro nodes representing macro components and standard cell nodes representing standard cell components;
generating an integrated circuit chip placement that places each node in the netlist data at a respective position on the surface of the integrated circuit chip, comprising:
obtaining a target value of a reward function that measures a quality of the integrated circuit chip placement; and
placing a respective macro node at each of a plurality of time steps according to a macro node order to generate a macro node placement of the macro nodes on the surface of the chip, the placing comprising, for each particular time step in the plurality of time steps:
   generating, from the netlist data, an input representation that characterizes at least (i) respective positions on the surface of the chip of any macro nodes that are before a particular macro node to be placed at the particular time step in the macro node order and (ii) the particular macro node to be placed at the particular time step;
   processing the input representation and the target value of the reward function using a macro placement neural network having a plurality of network parameters, wherein the macro placement neural network is configured to process the input representation in accordance with current values of the network parameters to generate a score distribution over a plurality of positions on the surface of the integrated circuit chip; and
   assigning the macro node to be placed at the particular time step to a position from the plurality of positions using the score distribution.

Clause 2. The method of clause 1, wherein generating the integrated circuit chip placement further comprises:
generating an initial integrated circuit chip placement, comprising placing each of the standard cells at a respective position on the surface of a partially placed integrated circuit chip that includes the macro components represented by the macro nodes placed according to the macro node placement.

Clause 3. The method of any preceding clause, wherein the plurality of positions comprise grid squares from an N×M grid overlaid over the surface of the integrated circuit chip.

Clause 4. The method of any preceding clause, wherein:
the macro placement neural network includes:
   a feature encoding neural network that is configured to:
      receive the input representation and process the input representation to generate an encoded representation of the input representation, and
      receive the target value of the reward function and process the target value to generate an encoded representation of the target value; and
   a policy neural network that is configured to process an input comprising the encoded representation of the input representation and the encoded representation of the target value to generate the score distribution.

Clause 5. The method of clause 4, wherein the macro placement neural network further comprises:
a value neural network that is configured to process the encoded representation of the input representation to generate a value estimate.

Clause 6. The method of clause 5, wherein the value neural network is not conditioned on the target value of the reward function.

Clause 7. The method of any one of clauses 4-6, wherein the input to the policy neural network further comprises visual features that are based on at least (i) the respective positions on the surface of the chip of any macro nodes that are before a particular macro node to be placed at the particular time step in the macro node order and (ii) the particular macro node to be placed at the particular time step.

Clause 8. The method of clause 7, wherein the visual features comprise an action mask that masks out positions on the surface of the chip that have a density that exceeds a threshold value based on at least (i) the respective positions on the surface of the chip of any macro nodes that are before the particular macro node to be placed at the particular time step in the macro node order.

Clause 9. The method of clause 7 or clause 8, wherein the visual features comprise a heatmap over the positions on the surface of the chip that represents, for each position, a respective cost of placing the particular macro node at the position given at least the respective positions on the surface of the chip of any macro nodes that are before the particular macro node to be placed at the particular time step in the macro node order.

Clause 10. The method of clause 9, wherein the respective costs are based on timing paths between macro nodes in the netlist data.

Clause 11. The method of any one of clauses 7-10, wherein the policy neural network is configured to process the visual features through a convolutional neural network to generate the score distribution, wherein one or more intermediate layers of the convolutional neural network are conditioned on the encoded representations of the target value and the input representation.

Clause 12. The method of any preceding clause, wherein the placing comprises, for each of one or more additional time steps in the plurality of time steps:
receiving a user input specifying a placement of a macro node to be placed at the additional time step; and
assigning the macro node to be placed at the additional time step to the position specified in the user input.

Clause 13. The method of any preceding clause wherein the macro placement neural network has been trained through supervised learning on a supervised training data set.

Clause 14. The method of clause 13, wherein, after being trained through supervised learning, the macro placement neural network has been fine-tuned through reinforcement learning on the netlist data.

Clause 15. The method of any preceding clause, wherein assigning the node to a position from the plurality of positions using the score distribution comprises:
generating a modified score distribution that sets to zero the score for each position for which a density determined based on the respective positions on the surface of the chip of any macro nodes that are before the particular macro node in the macro node order exceeds a threshold value; and
assigning the node using the modified score distribution.

Clause 16. The method of clause 15, wherein assigning the node using the modified score distribution comprises:
assigning the node to the position having the highest score in the modified score distribution.

Clause 17. The method of clause 15, wherein assigning the node using the modified score distribution comprises:
sampling a position from the modified score distribution, and
assigning the node to the sampled position.

Clause 18. The method of any preceding clause, further comprising:
outputting data specifying the integrated circuit chip placement.

Clause 19. The method of clause 18, wherein outputting data specifying the integrated circuit chip placement comprises outputting the integrated circuit chip placement to a component of an electronic design automation (EDA) software tool.

Clause 20. The method of clause 18, wherein outputting data specifying the integrated circuit chip placement comprises providing the data specifying the integrated circuit chip placement for presentation to a user on a user device.

Clause 21. The method of any one of clauses 18-20, wherein outputting data specifying the integrated circuit chip placement comprises providing the integrated circuit chip placement for fabrication of an integrated circuit chip according to the integrated circuit chip placement.

Clause 22. The method of any preceding clause, further comprising:
fabricating an integrated circuit chip according to the integrated circuit chip placement.

Clause 23. An integrated circuit chip having an integrated circuit chip placement generated by performing the operations of the respective method of any preceding clause.

Clause 24. A system comprising:
one or more computers; and
one or more storage devices communicatively coupled to the one or more computers, wherein the one or more storage devices store instructions that, when executed by the one or more computers, cause the one or more computers to perform the operations of the respective method of any one of clauses 1-22.

Clause 25. One or more non-transitory computer storage media storing instructions that when executed by one or more computers cause the one or more computers to perform the operations of the respective method of any one of clauses 1-22.

1. A method performed by one or more computers, the method comprising:
obtaining netlist data for an integrated circuit chip, wherein the netlist data specifies a connectivity on the integrated circuit chip between a plurality of nodes that each correspond to one or more of a plurality of integrated circuit components of the integrated circuit chip, and wherein the plurality of nodes comprise macro nodes representing macro components and standard cell nodes representing standard cell components;
generating an integrated circuit chip placement that places each node in the netlist data at a respective position on the surface of the integrated circuit chip, comprising:
obtaining a target value of a reward function that measures a quality of the integrated circuit chip placement; and
placing a respective macro node at each of a plurality of time steps according to a macro node order to generate a macro node placement of the macro nodes on the surface of the chip, the placing comprising, for each particular time step in the plurality of time steps:
generating, from the netlist data, an input representation that characterizes at least (i) respective positions on the surface of the chip of any macro nodes that are before a particular macro node to be placed at the particular time step in the macro node order and (ii) the particular macro node to be placed at the particular time step;
processing the input representation and the target value of the reward function using a macro placement neural network having a plurality of network parameters, wherein the macro placement neural network is configured to process the input representation in accordance with current values of the network parameters to generate a score distribution over a plurality of positions on the surface of the integrated circuit chip; and
assigning the macro node to be placed at the particular time step to a position from the plurality of positions using the score distribution.

2. The method of claim 1, wherein generating the integrated circuit chip placement further comprises:
generating an initial integrated circuit chip placement, comprising placing each of the standard cells at a respective position on the surface of a partially placed integrated circuit chip that includes the macro components represented by the macro nodes placed according to the macro node placement.

3. The method of claim 1, wherein the plurality of positions comprise grid squares from an N×M grid overlaid over the surface of the integrated circuit chip.

4. The method of claim 1, wherein:
the macro placement neural network includes:
a feature encoding neural network that is configured to:
receive the input representation and process the input representation to generate an encoded representation of the input representation, and
receive the target value of the reward function and process the target value to generate an encoded representation of the target value; and
a policy neural network that is configured to process an input comprising the encoded representation of the input representation and the encoded representation of the target value to generate the score distribution.

5. The method of claim 4, wherein the macro placement neural network further comprises:
a value neural network that is configured to process the encoded representation of the input representation to generate a value estimate.

6. The method of claim 5, wherein the value neural network is not conditioned on the target value of the reward function.

7. The method of claim 4, wherein the input to the policy neural network further comprises visual features that are based on at least (i) the respective positions on the surface of the chip of any macro nodes that are before a particular macro node to be placed at the particular time step in the macro node order and (ii) the particular macro node to be placed at the particular time step.

8. The method of claim 7, wherein the visual features comprise an action mask that masks out positions on the surface of the chip that have a density that exceeds a threshold value based on at least the respective positions on the surface of the chip of any macro nodes that are before the particular macro node to be placed at the particular time step in the macro node order.

9. The method of claim 7, wherein the visual features comprise a heatmap over the positions on the surface of the chip that represents, for each position, a respective cost of placing the particular macro node at the position given at least the respective positions on the surface of the chip of any macro nodes that are before the particular macro node to be placed at the particular time step in the macro node order.

10. The method of claim 9, wherein the respective costs are based on timing paths between macro nodes in the netlist data.

11. The method of claim 7, wherein the policy neural network is configured to process the visual features through a convolutional neural network to generate the score distribution, wherein one or more intermediate layers of the convolutional neural network are conditioned on the encoded representations of the target value and the input representation.

12. The method of claim 1, wherein the placing comprises, for each of one or more additional time steps in the plurality of time steps:
receiving a user input specifying a placement of a macro node to be placed at the additional time step; and
assigning the macro node to be placed at the additional time step to the position specified in the user input.

13. The method of claim 1, wherein the macro placement neural network has been trained through supervised learning on a supervised training data set.

14. The method of claim 13, wherein, after being trained through supervised learning, the macro placement neural network has been fine-tuned through reinforcement learning on the netlist data.

15. The method of claim 1, wherein assigning the node to a position from the plurality of positions using the score distribution comprises:
generating a modified score distribution that sets to zero the score for each position for which a density determined based on the respective positions on the surface of the chip of any macro nodes that are before the particular macro node in the macro node order exceeds a threshold value; and
assigning the node using the modified score distribution.

16. The method of claim 15, wherein assigning the node using the modified score distribution comprises:
assigning the node to the position having the highest score in the modified score distribution.

17. The method of claim 15, wherein assigning the node using the modified score distribution comprises:
sampling a position from the modified score distribution, and
assigning the node to the sampled position.

18. The method of claim 1, further comprising:
outputting data specifying the integrated circuit chip placement.

19. The method of claim 18, wherein outputting data specifying the integrated circuit chip placement comprises outputting the integrated circuit chip placement to a component of an electronic design automation (EDA) software tool.

20. The method of claim 18, wherein outputting data specifying the integrated circuit chip placement comprises providing the data specifying the integrated circuit chip placement for presentation to a user on a user device.

21. The method of claim 18, wherein outputting data specifying the integrated circuit chip placement comprises providing the integrated circuit chip placement for fabrication of an integrated circuit chip according to the integrated circuit chip placement.

22. The method of claim 1, further comprising:
fabricating an integrated circuit chip according to the integrated circuit chip placement.

23. A system comprising:
one or more computers; and
one or more storage devices communicatively coupled to the one or more computers, wherein the one or more storage devices store instructions that, when executed by the one or more computers, cause the one or more computers to perform operations comprising:
obtaining netlist data for an integrated circuit chip, wherein the netlist data specifies a connectivity on the integrated circuit chip between a plurality of nodes that each correspond to one or more of a plurality of integrated circuit components of the integrated circuit chip, and wherein the plurality of nodes comprise macro nodes representing macro components and standard cell nodes representing standard cell components;
generating an integrated circuit chip placement that places each node in the netlist data at a respective position on the surface of the integrated circuit chip, comprising:
obtaining a target value of a reward function that measures a quality of the integrated circuit chip placement; and
placing a respective macro node at each of a plurality of time steps according to a macro node order to generate a macro node placement of the macro nodes on the surface of the chip, the placing comprising, for each particular time step in the plurality of time steps:
generating, from the netlist data, an input representation that characterizes at least (i) respective positions on the surface of the chip of any macro nodes that are before a particular macro node to be placed at the particular time step in the macro node order and (ii) the particular macro node to be placed at the particular time step;
processing the input representation and the target value of the reward function using a macro placement neural network having a plurality of network parameters, wherein the macro placement neural network is configured to process the input representation in accordance with current values of the network parameters to generate a score distribution over a plurality of positions on the surface of the integrated circuit chip; and
assigning the macro node to be placed at the particular time step to a position from the plurality of positions using the score distribution.

24. One or more non-transitory computer storage media storing instructions that when executed by one or more computers cause the one or more computers to perform operations comprising:
obtaining netlist data for an integrated circuit chip, wherein the netlist data specifies a connectivity on the integrated circuit chip between a plurality of nodes that each correspond to one or more of a plurality of integrated circuit components of the integrated circuit chip, and wherein the plurality of nodes comprise macro nodes representing macro components and standard cell nodes representing standard cell components;
generating an integrated circuit chip placement that places each node in the netlist data at a respective position on the surface of the integrated circuit chip, comprising:
obtaining a target value of a reward function that measures a quality of the integrated circuit chip placement; and
placing a respective macro node at each of a plurality of time steps according to a macro node order to generate a macro node placement of the macro nodes on the surface of the chip, the placing comprising, for each particular time step in the plurality of time steps:
generating, from the netlist data, an input representation that characterizes at least (i) respective positions on the surface of the chip of any macro nodes that are before a particular macro node to be placed at the particular time step in the macro node order and (ii) the particular macro node to be placed at the particular time step;
processing the input representation and the target value of the reward function using a macro placement neural network having a plurality of network parameters, wherein the macro placement neural network is configured to process the input representation in accordance with current values of the network parameters to generate a score distribution over a plurality of positions on the surface of the integrated circuit chip; and
assigning the macro node to be placed at the particular time step to a position from the plurality of positions using the score distribution.
